(19) United States
(12) Patent Application Publication
(10) Pub. No.: US 2003/0001076 A1
(43) Pub. Date: Jan. 2, 2003

(54) System and methodology for the use of optical positioning system for scanners

(76) Inventors: Sarah M. Brandenberger, Boise, ID (US); Curt Van Lydegraf, Eagle, ID (US); Douglas G. Keithley, Boise, ID (US); Stephen B. Witte, Poway, CA (US)

Correspondence Address: HEWLETT-PACKARD COMPANY, Intellectual Property Administration, P.O. Box 272400, Fort Collins, CO, 80527-2400, US

(21) Appl. No.: 09/888,205

(22) Filed: Jun. 21, 2001

(51) Int. Cl. H01L 27/00

(52) U.S. Cl. 250/208.1

(57) ABSTRACT

The present invention is directed to a system and methodology in which the stepper motor (or a DC motor/encoder combination) of an optical scanning device is replaced by a DC motor which receives feedback information from an extended photodetector used in the scanner, or a proximately close second photodetector. The photodetector of current scanners may be extended (or a second photodetector may be incorporated) to read a margin marking located on, or attached to, the scanner body and the resolution of the extended portion, or separate photodetector, may be increased to accurately capture positioning information. The photodetector of the present invention detects the margin marking, typically located outside of the document scanning area, to determine positional information which is used by the processor to accurately determine position.

### TECHNICAL FIELD

The invention relates to imaging devices, more specifically, the invention relates to the use of an optical positioning system for use in scanning devices.

### BACKGROUND

Desktop scanners typically use stepper motors either to move an image array of imaging elements (e.g., Charged Couple Devices (“CCDs”)) across a sheet of paper (flatbed scanners), or to move a sheet of paper across the image array (sheetfeed scanners). Automatic Document Feeders (“ADFs”) may be used in combination with either flatbed or sheetfeed scanners to move individual pages into the scanning position, e.g., onto a scan window or into engagement with a feed mechanism.

Lines of pixels are generated as the image array is moved over the sheet of paper in flatbed scanners. Typically, the image array is moved at a constant velocity so that, with the imaging elements sampled at a constant rate, each resultant line of pixels is given a constant exposure time and represents a constant scan width. Thus, in these prior art scanners, the size of the pixels included in the scanned image is a direct function of the motion accuracy of the drive system. Stepper motors are often used to provide the high positional accuracy necessary to minimize distortion and support scan stitching.

Scan stitching is usually accomplished in one of two methods. The first method involves color plane registration in a color scanner that collects red, green and blue information in a single pass. The image array includes three rows of color sensitive photodetectors such as photodiodes that are physically separated. A first row of photodiodes detects red, a second green and a third blue light. For example the TCD-2903D Toshiba CCD image sensor has three linear array of 10,680 image sensing elements where each image sensing element is four microns by four microns on four micron centers to achieve an overall resolution of 1200 dots per inch. The red, green and blue sensitive rows are physically separated from each other on the image array by a vertical pitch of from one to eight times the horizontal pitch, typically representing 4, 8 or 12 array lines. The outputs from the three rows are then “stitched” back together to form a composite of RGB data representing a single image line. That is, after an image has been scanned, the information from each of the rows of photodetector (that is, the color planes) are later realigned by electronics or software in increments of one pixel or less. Thus, for example, the red and blue color planes will later be shifted into alignment with the central green color plane. Motion errors during repositioning of photodetector and fractional pixel errors are difficult to detect and correct after the image has been scanned. These residual position errors appear in the scanned image as “color fringes” around black-to-white edges.

The second method of stitch scanning involves stop/start repositioning of the image array or of the sheet of paper. Often a processing or device output speed constraint will cause the scanner to pause mid-scan. Examples of conditions causing speed constraints include insufficient memory to buffer the output from the scanner, an I/O delay, a busy host computer or a slow print engine receiving the scanned output. When a speed constraint is encountered, the scanner stops scanning and waits for the constraint to clear. Once the speed constraint is cleared, the image array or paper is backed up and reaccelerated to scanning speed so that scanning can begin at the precise point where it had previously stopped. If the scanning does not begin at the precise point, or if the scanning speed had not been attained, position errors will appear in the image as discontinuities or “jaggies.”

Color fringes and discontinuities or jaggies become even more noticeable if the scanned image is enlarged or scan resolution is increased. Furthermore, color fringes and jaggies can produce image distortions that severely reduce the accuracy of text recognition software, such as optical character recognition (“OCR”) programs.

The use of stepper motors in desktop scanners is advantageous because of the ease in which they can be controlled. A stepper motor also has sufficient torque to overcome inertia and friction incident in moving the carriage holding the image array with respect to the paper or the paper with respect to the aray. The use of a stepper motor also provides high positional accuracy. Two disadvantages associated with a stepper motor is that the associate torque ripple may detract from the quality of the scanned image and the relatively high cost of stepper motors.

U.S. Pat. No. 6,037,584, (“the '584 patent”) entitled Optical Scanner Including Exposure Control issued to Johnson et al. Mar. 14, 2000, which hereby incorporated herein by reference, discusses the replacement of the stepper motor with a DC motor. The scanner described in the '584 patent includes a photodetector, an encoder and an exposure control. Interaction between the photodetector, the encoder, and the exposure control results in a quality image using a relatively inexpensive DC motor. The photodetector includes at least one row of photodetector elements. The encoder includes an encoder wheel mounted on the shaft of the DC motor and detects relative motion of the object being scanned with respect to the detector, supplying an output which is representative of the relative motion such as position or velocity. The exposure control uses this representative output and generates a signal which is used to control the starting and the stopping of the exposure time for each scan line. For each line of pixels detected by the photodetector, the exposure control determines the appropriate exposure time and bases this determination on a specified amount of detected relative motion. Variations in the amount of relative motion causes inversely proportional variations in exposure time which ensures that the lines of pixels are of uniform size.

Replacement of the stepper motor in the scanner with a DC motor advantageously eliminates the torque ripple issue present in the stepper motor scanners by ensuring smooth operation during image array acceleration and motion at constant velocity. However, the use of the DC motor alone does not provide the high positional accuracy available from the stepper motor. In order to provide required positional accuracy with the DC motor, position feedback is introduced into the system. Position feedback may be accomplished through the use of an encoder wheel. The most common type of encoder wheel is a quadature encoder wheel associated with the motor shaft. The quadature encoder wheel generates two signals which are 90° out of phase with each other. The encoder wheel's signals are thus needed to accurately determine and control the relative motion of the image array.

In some prior art systems the encoder may be optical with appropriate logic to determine relative position of the image array. In these systems, an optical encoder detects motion of the shaft mounted encoder wheel to determine positional information. Since DC motors cannot independently provide precise position of the image array, positional information is derived from mounting the encoder wheel on the motor shaft and providing appropriate circuitry to detect encoder wheel position and/or movement. Typically, the circuitry includes a separate light source and optical detector with associated logic circuitry, adding to the cost of the motor assembly and offsetting part of the cost advantage of using a DC motor.

Thus, in each of these prior art systems, a stepper motor or a DC motor with an encoder is used to move the image array across a sheet of paper to be scanned or to move the sheet of paper to be scanned across the image array. In each of these cases, the stepper motor or the DC motor and encoder are used for positional information. The inclusion of these motors increases the cost of the associated scanner device. Thus, a need exists to reduce the cost of scanner equipment through the elimination of precise stepper motors or DC motors with encoders while maintaining, or increasing, scanner precision.

### SUMMARY OF THE INVENTION

The present invention is directed to a system and method in which an optical scanning system includes an optical imaging array with at least one row of photodetector elements. The photodetectors include a main group configured to optically scan a media to provide an electronic representation of an image formed on the media.. A peripheral group of the photodetectors are arranged to detect a positioning mark or element indicative of a position of the imaging array relative to the media being scanned. Position information may be derived by markings provided adjacent to a scanning window or on some other encoding device. A processor uses the markings to calculate the position of the array with respect to a scanned image. Where the markings are permanently affixed to a scanner system body, the markings may include a repetitive pattern of a single image such that the processor counts the number of times the markings are scanned to determine a position of a particular row of photodetector elements.

The peripheral photodetectors may be scanned at a higher rate or frequency than the main group to increase the frequency of position update information to some multiple of the line output rate. The increased frequency of position update information may be accomplished by interleaving data from the peripheral group of photodetectors into the bit stream received rom the main group of photodetectors, the peripheral group being accessed more than once per image line. A geometry of the peripheral photodetectors may be adjusted to accommodate the higher frequency of operation by, for example, requiring the peripheral photodetectors to be more sensitive or larger than those of the main group of less frequently scanned photodetectors

### BRIEF DESCRIPTION OF THE DRAWING

FIG. 1 is a diagram of a flatbed scanner according to an embodiment of the present invention;

FIG. 2 is a diagram of the orientation of the image array and the bed of the flatbed scanner of FIG. 1;

FIGS. 3A through 3E are diagrams of the alternate markings which determine the image array's position with respect to the flatbed scanner bed;

FIG. 4 is a diagram of the imaging element sensing the margin markers;

FIGS. 5A through 5D are diagrams of the alternate embodiments of an image array including extensions for detecting the margin markers;

FIG. 6 is a diagram of a row of imaging elements including document and position detecting portions together with a timing diagram showing output from both portions time multiplexed together; and

FIG. 7 is a schematic diagram of a timing circuit for time-multiplexing outputs from dedicated position sensing imaging elements into a data stream from a larger array of document imaging elements.

### DETAILED DESCRIPTION

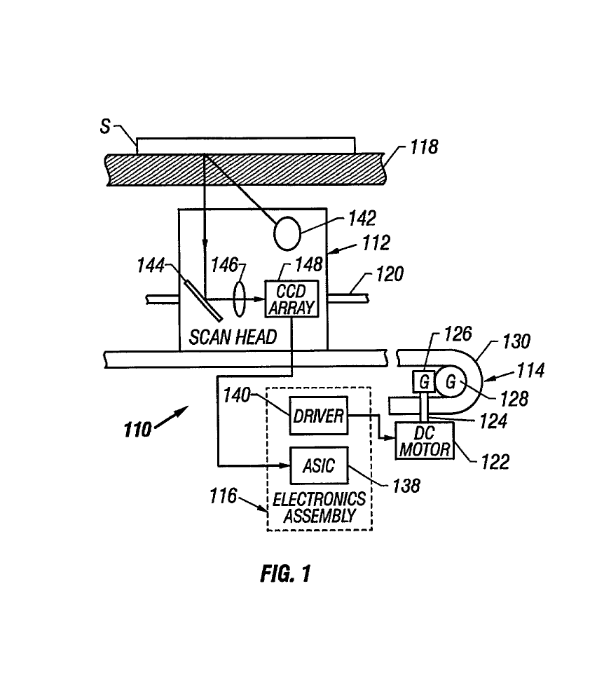

FIG. 1 is a block diagram of a flatbed scanner 110. Flatbed scanner 110 includes scan head 112, DC motor drive assembly 114, electronics assembly 116, glass pane 118 and housing (not shown). Glass pane 118 and the housing form an enclosure inside which scan head 112, motor drive assembly 114 and electronics assembly 116 are mounted.

DC motor drive assembly 114 includes one or more slider rods 120, or their functional equivalent, for guiding scan head 112 in a linear direction along glass pane 118 and DC motor 122, and transmission for moving scan head 112 along slider rods 120. Of course, other configurations for the DC motor drive assembly may be used including, for example, a single slider rod and an opposing wheel. DC motor 122 can be a brush or brushless DC motor that rotates at speeds between twenty and six thousand rpm. The transmission is typical to flatbed scanners: motor shaft 124 turns worm gear 126, which drives gear 128 which turns timing belt 130. Timing belt 130 moves scan head 112. It takes a number of motor shaft revolutions to move scan head 112 an inch along slider rods 120.

Electronics assembly 116 includes application specific integrated circuit (“ASIC”) 138 and DC motor driver 140 such as an H-bridge motor driver. Driver 140 has an input that is adapted to receive pulse width modulated (“PWM”) signals from a motion controller/speed controller implemented on ASIC 138. The PWM signals cause DC motor driver 140 to selectively energize field windings of DC motor 122 to create a desired motor torque. The PWM signals can cause DC motor 122 to rotate shaft 124 in either a clockwise or counterclockwise direction.

As described further below, in a preferred embodiment of the present invention image array 148 includes a position determining mechanism which feeds positional information to ASIC 138. By using this positional information ASIC 138 controls driver 140 to selectively power DC motor 122 to move the image array at a constant velocity.

To scan a sheet S of paper, sheet S is positioned atop glass pane 118, and a host (e.g., a personal computer) causes electronics assembly 116 to begin a scanning operation. The host might also supply a scan resolution parameter value such as 1200 dots per inch (“DPI”) to electronics assembly 116. Under control of ASIC 138, DC motor drive assembly 114 moves scan head 112 along slider rods 120 to a known position (e.g., a calibration area near one extreme of scan head travel), performs desired calibration and/or white balancing, and then starts moving scan head 112 along slider rods 120. Fluorescent bulb 142 of scan head 112 is turned on to illuminate a portion of sheet S with white light, and optics assembly 144, 146 focuses an image of the illuminated portion onto image array 148. Image array 148 is exposed to, and integrates, a line of pixels at a time, and electronics assembly 116 processes signals generated by image array 148 and sends the processed signals to the host. Sheet S is scanned, line-by-line, as scan head 112 is moved along slider rods 120.

ASIC 138 includes an exposure control, which adjusts the exposure time of image array 148 such that exactly one pixel distance is traversed during each exposure time, regardless of any small position or velocity errors in controlling DC motor 122. The exposure control generates a transfer gate signal for each channel of image array 148. To scan a line, the exposure control de-asserts the transfer gate signal to begin an exposure time, processes the encoder pulses derived from position sensing portion of the image array located along one side of the scan head and then asserts the transfer gate signals to stop the exposure time after a specified amount of relative motion has occurred. The transfer gate is then restarted for the next exposure. Thus, the exposure control varies the exposure time to ensure that each exposure time corresponds to the same scan head displacement and that the lines of pixels in a scanned image are all of uniform size. Such an exposure control allows DC motor 122 to be used in low cost commercial scanning products.

ASIC 138 can optionally include a servo loop for compensating for intensity and spectrum drift of fluorescent bulb 142. ASIC 138 also includes a gain compensation control for adjusting gain to maintain a uniform exposure level. The exposure level is a product of reflected light intensity from the object being scanned, image array responsivity, exposure time, and gain. The reflected light intensity and the image array responsivity are relatively constant throughout a scan. Therefore, the exposure level is held at a relatively uniform level by decreasing the gain to offset an increase in the exposure time, and by increasing the gain to offset a decrease in exposure time.

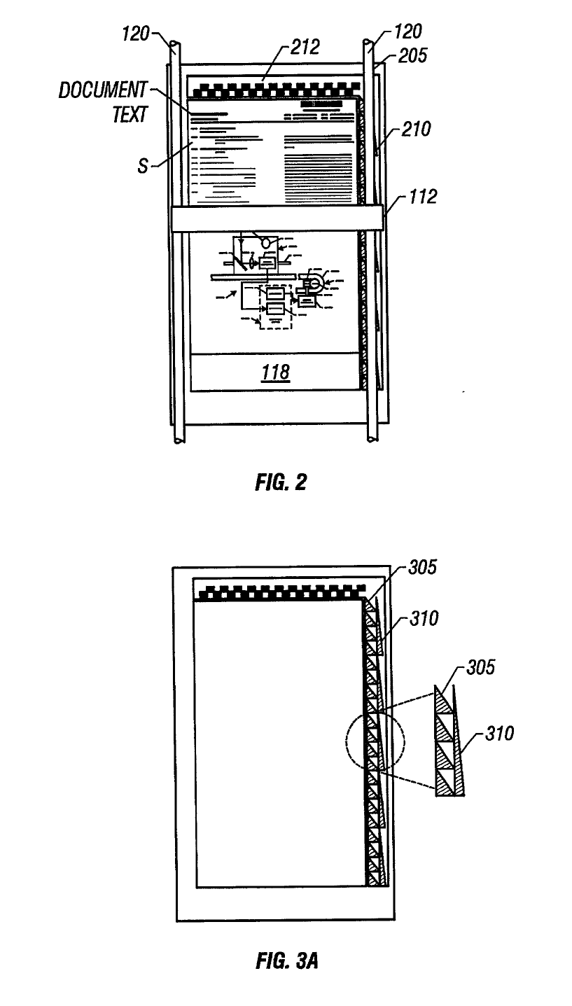

Reference is now made to FIG. 2, which shows a flatbed scanner's scan head 112 positioned over sheet S containing text as viewed through glass pane 118. As scan head 112 travels across sheet S, the photodetector (not shown) accumulate charge, and when a transistor gate (not shown) signal is asserted, the charge is transferred to an analog shift register of the device capturing the image on the sheets immediately below the photodetector. In addition to capturing the information on sheet S, the photodetector of the image array also obtains positional information from flatbed scanner bed 205. In FIG. 2, margin markings 210 (partially obscured by slider rods 120) are positioned along sheet S which ensures the image array can determine the relative position of the scanned portion of sheet S with respect to other scanned positions of sheet S. While a specific form of margin markings 210 are shown in FIG. 2, any designs, markings, or any other method of markings which allow the image array to calculate its position accurately is acceptable. Additional codes, signals or markings can be included in this field to instruct the image array to take specific action. For example, a distinct marker may be placed on the last scannable line to indicate scan head 112 has reached the end of the scannable area. The margin markings information from scan head 112 is sent to ASIC 138 which processes the information to determine positional information.

In addition to margin markings 210, calibration region 212 may be positioned at a rest position of image array 148. This region may be imprinted with appropriate markings so that the image array can be properly positioned at the start of the scan window and provides a known light reflective surface for lamp and photodetector calibration. Margin markings 210 and calibration region 212, by way of example, may be formed by printing onto an “L” shaped label that may be affixed onto the bottom of the chassis supporting glass pane 118.

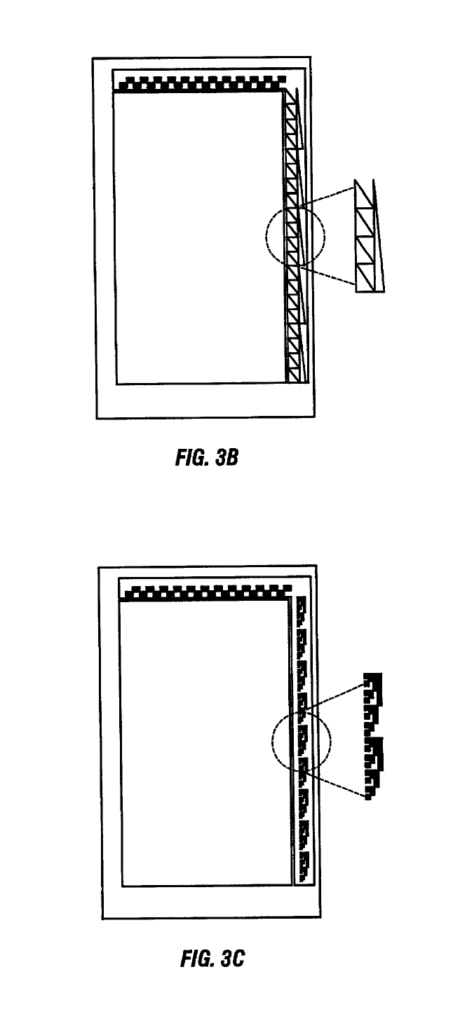

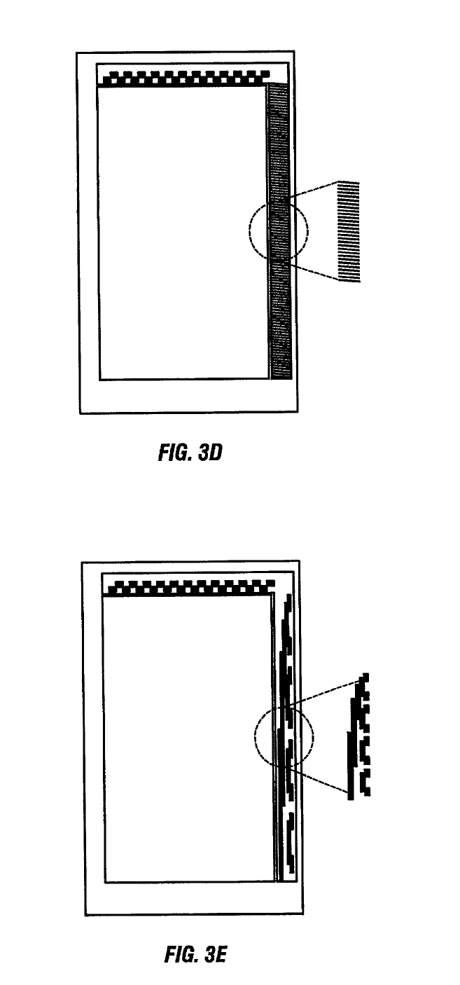

FIGS. 3A-3E show additional margin markings which may be used to determine positional information. For example, FIG. 3A shows twenty right triangles 305 down the right hand side of the scanner margin. Accurate positional information is obtained from ASICs 138's calculations concerning what portion of current right triangles 305 is being viewed by the image array and by counting how many previous right triangles 305 have been viewed during the scanning operation. Additionally, longer right triangles 310 can be included to aid in positional information. FIG. 3B shows an additional right triangle configuration which may be alternatively used.

FIG. 3C shows a binary pattern used as margin markings which allows ASIC 138 to determine its positional information accurately for each scan head 112 position within the repetitive patterns. For example, if groups of binary scale margin markings are one inch in length, and the scanner is operating at 1200 dots per inch, the image array will capture a portion of the binary scale margin markings 1200 times; and each of the 1200 times will allow a calculation of a unique vertical position within the binary scale markings. In addition by counting the number of complete groups of binary scale margin markings which have already been scanned ASIC 138 will correctly determine the position of the image array. Similarly, the margin markings of FIGS. 3D (diagonal marks) and 3E (grey code) may be used. In particular, the arrangement of FIG. 3D provides multiple, angles lines for use with a linear arrangement of photodetector, providing enhanced position sensing capabilities. For example, a linear array of 50 photodetector may be used to detect passing of corresponding portions of each line as the scan progresses. Thus, the margin markings of FIG. 3D provide an accurate determination of position. One skilled in the art would understand that other geometries or markings, such as numbers, letters, shapes of varying size, etc., may be used in addition to those depicted in FIGS. 3A-3D. For example, the markings may consist of special characters, optical noise, or other predefined and/or random patterns of pixels used to determine position. Further markings may include pixel intensity information to provide position information. For example, each of the previously described patterns or other patterns may include grey scale and/or color variations related to position. Still further the markings may comprise grey scale and/or color variations alone so that positional information is inferred from luminance independent of pixel geometry.

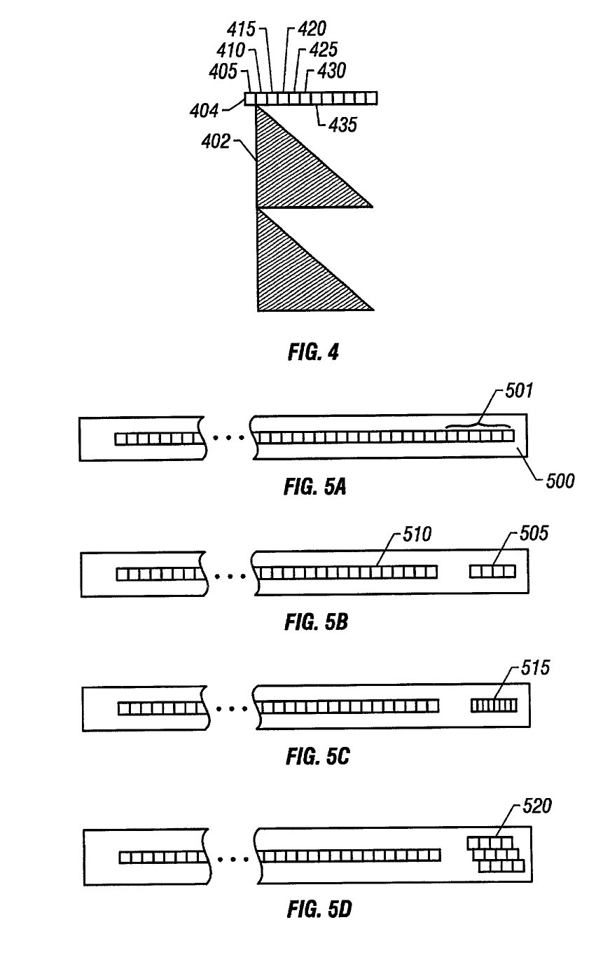

FIG. 4 is a diagram which is used to explain how the individual photodetector elements of the image array are used to determine positional information within each individual margin marking of overall margin marking 210. At time t=0, the portion of margin marking 402 underneath the image array blocks light from single photodetector element 405 of image array 404. As time passes, image array 404 moves across margin marking 402. For instance at time=1, only photodetector elements 405 and 410 may receive less light from flourescent bulb 142 (FIG. 1) indicating a dark marking underneath it. At a later time, Photodetector elements 405, 410 and 415 may receive less light indicating the dark markings. By knowing the site of individual margin markings 402, and the size of the photodetector elements, calculations can be performed which relate light received by the individual photodetector elements to the vertical position of image array 404 within the specific margin markings.

The portion of image array 148 (FIG. 1) dedicated to reading the margin markings may require additional resolution to allow accurate position determination. One skilled in the art would understand that the number of imaging elements required, and their resolution, is dependent on the margin markings, and the desired accuracy of the positional information.

FIGS. 5A-5D show alternate embodiments of a image array including extensions for accurately detecting margin markings. FIG. 5A is a diagram of the image array in which photodetector elements 500 have been extended 501 to accurately capture margin marking 210 information. FIG. 5B is a diagram which includes separate image array 505 from main image array 510 for reading margin markings 210. FIG. 5C is a diagram of separate, higher resolution image array 515 for accurate scanning of margin markings 210. FIG. 5D is a diagram of a multi-rowed, stepped image array 520 which allows enhanced resolution in detecting margin markings 210.

Enhanced positional accuracy may be achieved by another aspect of the invention without the addition of additional dedicated support circuitry. In particular, a scanner, using a first array of photodetectors to image a media such as a document, and another array of photodetectors to detect position markings, interleaves the signal form the two arrays. A sampling rate of the position detecting array is higher than that of the main array to provide enhanced position information and thereby enhanced positioning control. This may be accomplished by issuing start pulses to the position detecting array more frequently than issued to the main array. For example, after every fifteenth clock signal used to shift image data out from the main array, one clock signal may be generated to shift image data out from the positioning array. Since the positioning array is generally much smaller than the main array, it will be completely scanned more frequently than the main array. Further, by interleaving or time-multiplexing the outputs from both arrays, there is only need for a single sensor interface to handle both arrays. This configuration further avoids additional pins, chip real estate, and power otherwise required to provide two distinct image arrays as might be used to implement different array sampling rates. The configuration also avoids duplicating peripheral electronics required process the output of two arrays.

For example, using a linear array of photodetectors, a start signal is typically issued at the beginning of each line to be read. This start pulse causes a transfer of the sensor's values to a storage area and resets the sensors to begin accumulating charge for a subsequent image line. In addition to the start signal, several timing signals are used to serially clock the image data out from the array to the output pins of the imaging device, commonly including one output pin or terminal per color. Typically, the sample rate of the photodetector is considered to be, as most, the clock-out frequency divided by the number of pixels. For a 600 pixel-per-inch (ppi) sensor scanning a 8½ inch (i.e., 5100 pixel) wide document with a clock-out frequency of 2 Mpixels/second, the line sample rate is 392 Hz

$$( i . e . , \frac{2.0 \times {10}^{6}}{600 \times 8.5} )$$

resulting in a period of 2.55 microseconds.

Rather than use a completely separate array of photodetectors for detecting array position, a small positioning array of detectors 602 is added to the main array. For the purposes of this illustration, we may assume that the smaller array includes a line of 16 photodetectors, i.e., detects 16 pixels at one side of the main array, the main array configured to detect a line of 5100 pixels. To achieve an increased frequency of positional data, over and above the 392 Hz of the main array, data from the smaller array may be periodically interleaved with the output of the main imaging array. For example, if an output sample from the smaller positioning array were inserted after every fifteenth sample obtained from the main array, the complete 16 pixels of the smaller positioning array would be available every 256 transfer clock cycles. That is, by providing a separate start pulse to the integral smaller positioning array every 256 samples, the 16 bit positioning array would have a sample rate of 7800 Hz, i.e., a period of 128 μsec.

To accommodate the increased operating frequency of the positioning array, its constituent photodetectors may be suitably configured or selected. That is, since the exposure time decreases with increased sampling frequency, the detectors may be made more light sensitive by, for example, increasing their physical or optical size. A horizontal expansion of the photodetector size may be limited by the desired horizontal resolution required by the position markings, while a vertical size is limited by a similar need to maintain an acceptable vertical resolution. Thus, the individual photodetectors may be enlarged in either or both horizontal and vertical directions to provide increase light sensitivity to the extent required resolution is achieved.

In addition to modifying the optical size of the detectors to accommodate reduced exposure time, appropriate electronics may be used. For example, an amplifier may be provided at the output of the photodetectors to provided increased sensitivity.

By interleaving, the larger main array would take slightly longer to clock out data (i.e., 1/15 longer or 7% in the current illustration.) Conversely, the same analog electronics used to support a “normal” linear sensor array is used to provide both imaging and positional data. Separation of the two signals may be accomplished by the digital ASIC of the scanner as it normally corrects the incoming data without incurring additional costs to the system.

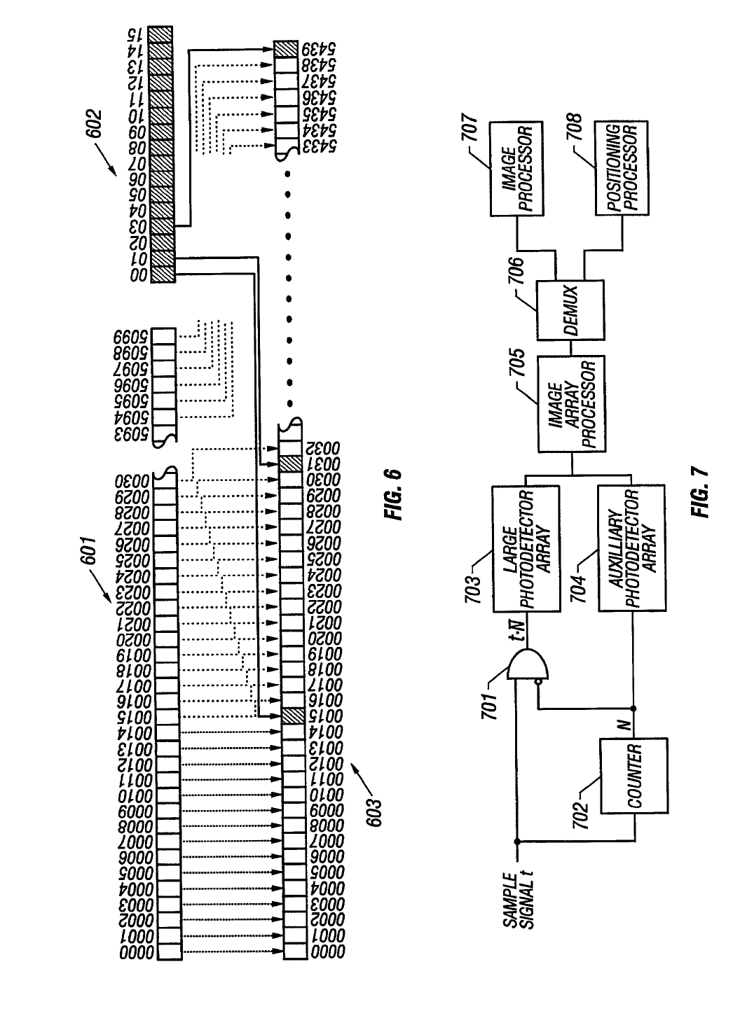

FIG. 6 illustrates this scheme of interleaving image pixels with positioning pixel data. Referring to the figure, an imaging array includes a large main image array of 5100 photodetectors 601 and a smaller, positioning array of 16 photodetectors 602. A serial output from the array is shown as data stream 603, with every sixteenth output representing a pixel of positioning array 602. Thus, as previously detailed, all 16 pixels of positioning array 602 are updated and made available every 256 pixels, or 21¼ times per line of image data, i.e., over twenty times “faster” or more frequently than provided by the large main array.

FIG. 7 is a schematic diagram of a hardware implementation of such an interleaving scheme. A clock signal labeled “sample signal t” is provided in parallel to AND gate 701 and modulo N counter 702. In this case, counter 702 is configured to provide an output signal responsive to a count of 16 and then to reset to zero. This output is supplied to auxiliary photodetector array 704 causing it to clock out a next pixel of it 16 pixel image array portion. At the same time, an inverted signal from counter 702 is supplied as an input to AND gate 701, thereby inhibiting sample signal t from being applied to large photodetector array 703. The net result is that, every 16^{th} clock cycle, pixel data from auxiliary photodetector array 704 is interleaved into the pixel data stream from large photodetector array 703. The combined outputs from both arrays 703 and 704 are thereby time multiplexed and processed in common by image array processor 705. Image array processor 705 may include components which would be common between the image processing path and the positioning processor path. For example, image array processor 705 may include analog to digital conversion, a correlated double sampling block with a CCD (in a CMOS photodetector array a sample and hold amplifier used in conjunction with an offset correction are commonly used), offset correction and gain correction. The output from image array processor 705 is then split into its image and positioning data components by demultiplexer 706, the image component provided to Image Processor 707, the positioning data provided to positioning processor 708.

As those of ordinary skill in the art will recognize, while the system of FIG. 7 depicts separate functional blocks used to properly time the arrays so as to form a fully interleaved output signal, process that output, and then distribute the processed signals to the appropriate image or positioning processor functions, other architectures and arrangements may be employed to provide a higher sampling rate for one portion of an imaging array including interleaving such high rate data in with the remaining data from the array. Further, although an embodiment of the invention has been described to insert positional pixel information between every 15 image pixels, other techniques of combining the position and image pixels may be used within the scope of the invention.

What is claimed is:

1. An optical scanning system comprising:
a photodetector including at least a first row of photodetector elements;
margin markings positioned so as to be viewed by at least one of said photodetector elements; and
a processor for calculating the position of the row of photodetector elements with respect to a scanned image, said calculations based, at least in part, by detection of said margin markings.

2. The optical scanning system of claim 1 further comprising an exposure control for controlling the amount of time said photodetector is exposed.

3. The optical scanning system of claim 1 wherein margin markings are a series of diagonal lines.

4. The optical scanning system of claim 1 wherein the margin markings is outside a document viewing area.

5. The optical scanning system of claim 4 wherein the margin markings are permanently affixed to a scanner system body.

6. The optical scanning system of claim 1 wherein said margin markings are a repetitive pattern of a single image and said processor counts the number of times the image is scanned to determine said position of row of photodetector elements.

7. The optical scanning system of claim 1 wherein said photodetector elements configured to view said margin markings are operated at higher speed than the speed of remaining ones of said photodetector elements.

8. The optical scanning system of claim 1 wherein said photodetector elements configured to view said margin markings are sampled at a higher frequency than remaining ones of said photodetector elements.

9. The optical scanning system of claim 1 wherein said photodetector elements configured to view said margin markings are configured to be more light sensitive than remaining ones of said photodetector elements.

10. The optical scanning system of claim 1 wherein said photodetector includes at least a second row of photodetector elements wherein said first row and said second row of photodetector elements form an array.

11. A method of optical scanning comprising the steps of:
optically detecting document images in a document viewing area;
optically detecting coding images; and
calculating a position of a detected document image from detected ones of said coding images.

12. The method of claim 11 further comprising a step of adjusting exposure times based on said calculated position.

13. The method of claim 11 wherein the coding images are permanently affixed to a scanning system body.

14. The method of claim 11 wherein said coding images are a series of repeated images.

15. The method of claim 11 wherein said coding images are outside said document viewing area.

16. An optical scanning system comprising:
an optical window;
an array of optical detectors such that a portion of said linear array of optical detectors extends beyond said optical window;
optically detectable code provided adjacent to said optical window and detectable by said portion of said linear array of optical detector which extend beyond said window;
means responsive to said optically detectable code for providing position information; and
means configured to receive position information from said logic circuit.

17. The optical scanning system of claim 16 wherein the array of optical detectors is mounted in a movable carriage.

18. The optical scanning system of claim 16 wherein the array of optical detectors are Charged Coupled Devices.

19. The optical scanning system of claim 16 wherein said drive circuit includes a DC motor.

20. The optical scanning system of claim 16 wherein the portion of said array of optical detectors which extends beyond said optical window includes optical detectors which provide a resolution different from the optical detectors which are within said optical window.

21. An optical array comprising:
a photodetector array including first and second groups of photodetectors;
means for causing said first group of photodetectors to provide first pixel data at a first rate;
means for causing said second group of photodetectors to provide second pixel data at a second rate higher than said first rate; and
an output supplying said second pixel data interleaved with said first pixel data.

22. The optical array of claim 21 further comprising a processor configured to process said second pixel data interleaved with said first pixel data.

23. The optical array of claim 21 wherein said second pixel data is interleaved with said first pixel data using time multiplexing.

24. The optical array of claim 21 wherein said second data rate is at least twice said first data rate.

25. The optical array of claim 21 wherein said first group of photodetectors includes a greater number of photodetectors than a number of photodetectors comprising said second group of photodetectors.

26. The optical array of claim 21 wherein said first group of photodetectors are arranged to image a media to be scanned and said second group of photodetectors are arranged to detect a position of said optical array relative to said media.

27. The optical array of claim 21 wherein said first and second groups of photodetectors include a plurality of photodetectors, said photodetectors of said second group being more sensitive to light than said photodetectors of said first group.

28. The optical array of claim 21 wherein said first and second groups of photodetectors are linearly arranged..

29. The optical array of claim 21 wherein said second group of photodetectors are arranged in a plurality of rows.

30. The optical array of claim 21 wherein said second pixel data are used to provide imaging information from which positioning information can be inferred.

31. An optical scanning system comprising:
an optical window;
a photodetector array including first and second groups of photodetectors;
a first clock signal configured to cause said first group of photodetectors to provide first pixel data at a first rate;
a second clock signal configured to cause said second group of photodetectors to provide second pixel data at a second rate higher than said first rate;
an output supplying said second pixel data interleaved with said first pixel data;
a logic circuit responsive to said second pixel data for providing position information; and
a drive circuit configured to receive position information from said logic circuit.

32. The optical scanning system of claim 31 wherein said photodetector array is mounted in a movable carriage.

33. The optical scanning system of claim 31 wherein said photodetector array comprises Charged Coupled Devices.

34. The optical scanning system of claim 31 wherein said drive circuit includes a DC motor.

35. The optical scanning system of claim 31 wherein said second group of photodetectors extends beyond said optical window.
